(19) United States
(12) Patent Application Publication
(10) Pub. No.: US 2011/0057602 A1
(43) Pub. Date: Mar. 10, 2011

(54) APPARATUS WITH ELECTRIC ELEMENT POWERED BY A CAPACITIVE CERAMIC-BASED ELECTRICAL ENERGY STORAGE UNIT (EESU) WITH CHARGING INTERFACE AND WITH ON-BOARD ENERGY GENERATION

(76) Inventor: John Boyd Miller, (US)

(21) Appl. No.: 12/878,373

(22) Filed: Sep. 9, 2010

Related U.S. Application Data
(60) Provisional application No. 61/276,211, filed on Sep. 9, 2009.

(51) Int. Cl. H01M 10/46; H05K 7/14; H02J 7/00

(52) U.S. Cl. 320/101; 307/149; 320/166

(57) ABSTRACT

Within an apparatus (20), an electrical-energy-using element (electric element) (30) is capable of receiving power from a capacitive, ceramic-based electrical energy storage unit (EESU) (100). An EESU (100) power source within the apparatus is capable of being recharged via an on-board EESU charging interface (110) with energy from an on-board electrical energy source (140).

This Non-Provisional Application Claims the Benefit of the Priority Date of Provisional Application No. 61/276,211 Filed Sep. 9, 2009.

### CROSS REFERENCE TO RELATED APPLICATIONS

Not Applicable

### FEDERALLY SPONSORED RESEARCH

Not Applicable

### SEQUENCE LISTING OR PROGRAM

Not Applicable

### BACKGROUND OF THE INVENTION

1. Field of Invention

This invention relates to energy storage, energy storage charging, on-board electrical energy generation, and energy usage within an apparatus, specifically, an apparatus contains an electrical-energy-using element (electric element), a capacitive, ceramic-based electrical energy storage unit (EESU) that is capable of operating as a power source or as a primary power source for the electric element, an interface for charging the EESU, and on-board energy generation that is capable of charging the EESU through the charging interface.

2. Background of the Invention

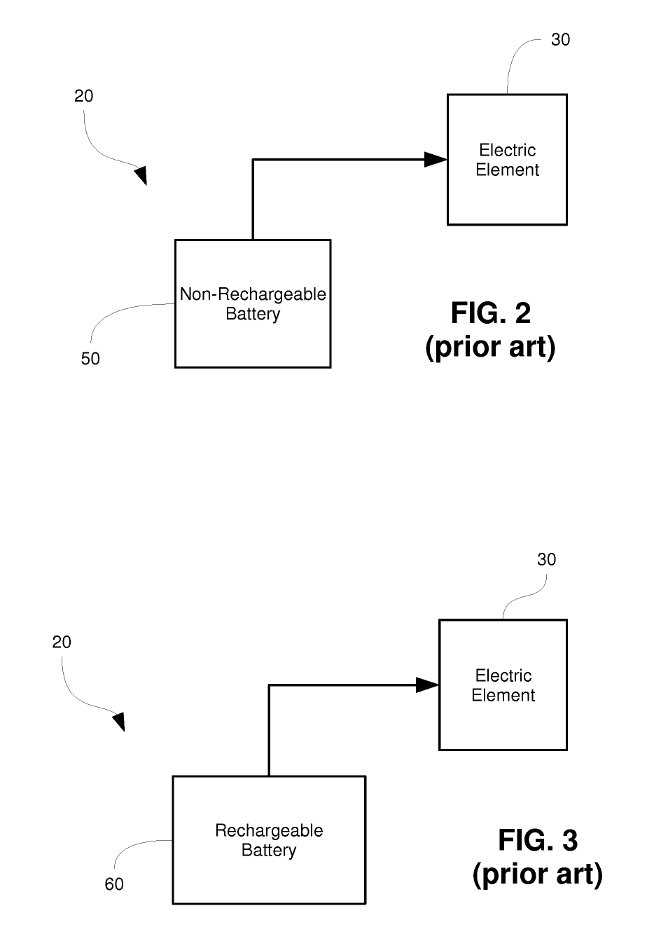

There are many devices that currently utilize electro-chemical battery electric power as their primary energy source, FIGS. 2, 3 and 5. A key feature of these devices is the convenience of not needing to be tethered to an electrical source such as a wall socket via a cord. This makes them excellent for use in remote locations, and when they are small enough to be portable, they are highly convenient for users on the go.

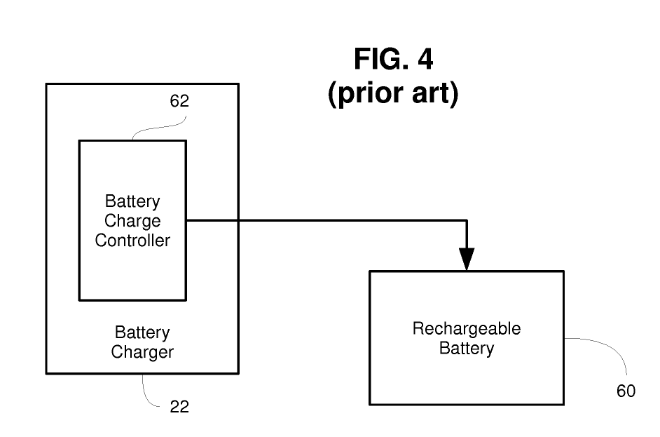

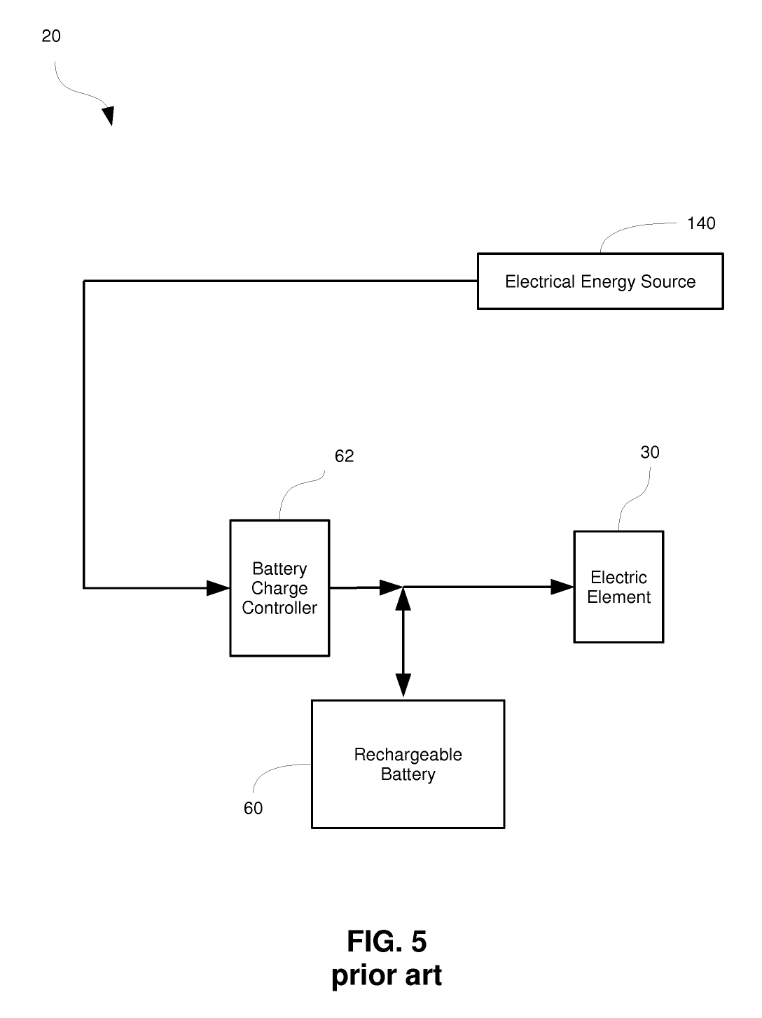

In some devices that get their power from a rechargeable battery, such as is the case with power tools like drills, saws, and lights, the battery is recharged in a stand-alone battery charger, FIG. 4. In other devices with a rechargeable battery however, a built-in energy source is available in the device to recharge the battery, as shown in FIG. 5. Many electric and electronic devices such as common calculators utilize a solar collector energy source with a battery to allow them to be highly portable and to require little external energy and few battery change-outs over the life of the device. This is also popular in some devices such as solar-powered walkway lights around a home, remote highway signs and emergency warning systems that use a solar collector to recharge a battery whenever there is enough light to allow it. Yet other systems are built around energy generation and store energy in batteries, these include renewable energy generation systems such as windmills, solar collectors, and even waterway paddle wheels. Other devices, such as hybrid electric vehicles and electric auxiliary power units (APU) for over-the-road trucks with sleeper units, utilize an internal combustion engine as an on-board energy source to charge a battery. Some power sources are small enough to allow their use in highly portable applications. Thus, using a built-in energy source allows not only the convenience of recharging a device without removing the battery from the device and without connecting the device to an external power source such as a wall socket, but it also allows many portable devices extended functionality by recharging on-the-go, and it provides a great resource for power for remote commercial, military, and emergency use devices when no other power is available.

The rechargeable batteries in such devices, while potentially lasting for many recharge cycles, eventually get to a point where they can no longer hold a charge, they become marginally useful, and ultimately they must be disposed of. Changing out these batteries causes the user to incur costs in money as well as in time. Also, as these rechargeable batteries are disposed of, they require time, effort and cost to recycle them, or if they are not recycled, they create waste and possibly pollution.

Most, if not all, batteries have shelf life issues. Shelf life is the amount of time an electro-chemical battery can sit on a shelf before its chemistry degrades to the point that it will no longer hold a charge. The longest shelf life for popular batteries is about ten years, after which they must be replaced. Most Lithium-Ion (LiIon) batteries have a shelf life of about 10 years. Lead-acid batteries utilized in outdoor environments, such as with most vehicles, have a shelf life of 5 to 8 years. And popular alkaline AA or AAA batteries have a shelf life of less than 5 years, as can be readily seen by their purchase-by dates. Temperature, chemical memory issues, and the number of deep-charge cycles a battery goes through also limit the useful life of most batteries.

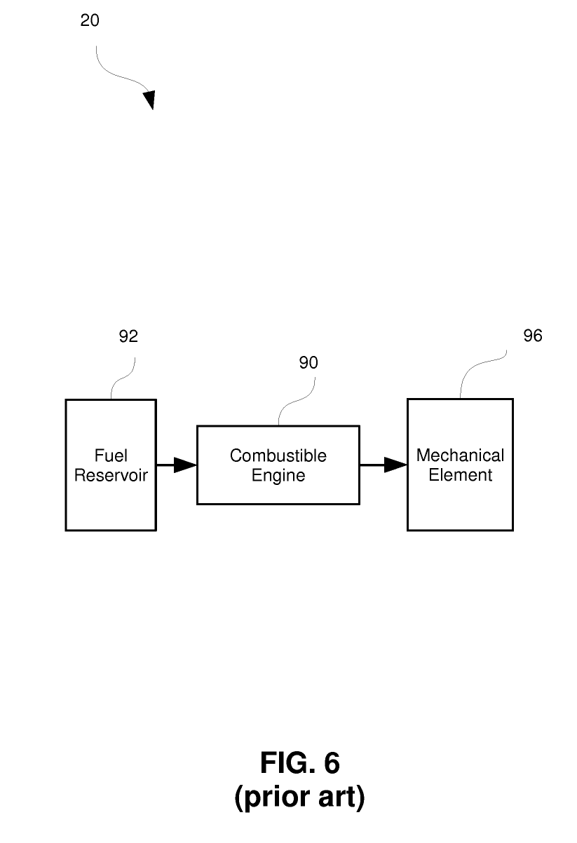

In the place of using an electro-chemical battery for power, many portable devices utilize gasoline, diesel, propane, or natural gas powered internal combustion engines to provide portable utility, FIG. 6. Examples of such devices are gas powered yard maintenance tools such as mowers, trimmers and blowers. Other examples are portable road signs and lights with gas or diesel powered engines that generate electrical energy to power the lights. Still others include portable electric generators or backup generators that utilize an internal combustion engine to provide emergency power to homes, hospitals, businesses or other locations when another source of electric power is not available. And of course the most popular examples of portable devices that utilize internal combustion engine power are vehicles, watercraft, and aircraft.

For devices that utilize internal combustion engines, the advantages are quite apparent in that with a little combustible fuel, the devices can provide a useful amount of work. The disadvantages to utilizing this type of power for an apparatus include the requirements of handling, storage, and delivery of dangerous toxic and explosive fuels. Another disadvantage of this type of power generation is that these engines require regular maintenance to perform properly. Maintenance of these engines also requires the use, storage, and handling of somewhat messy lubrication oils. Another disadvantage is that the overall conversion efficiency of energy for useful work using an internal combustion engine is low. Even when an apparatus is idling and performing no useful work, energy is being expended. Engine exhaust is also a contributor to pollution. Also, few if any devices with an internal combustion engine can supplement or replenish the energy utilized by their engines with on-board energy generation methods, as can devices based on batteries that include on-board energy generation capabilities such as solar power generation via solar cells.

A lesser used source of portable power storage in an apparatus is capacitors. While devices that utilize capacitors, supercapacitors, or ultracapacitors cannot store nearly the same amount of energy as many popular batteries, a device based on an ultracapacitor is capable of storing energy and is generally quite reliable for 10 years or so without changing out the capacitor power source, except in extreme temperatures, voltages, or even extreme storage conditions, which cause their charge holding and charge delivering capacities to degrade.

As can readily be seen in the marketplace, capacitors are not popular as a primary power source in devices. The main reason for this is most likely their low energy storage capacities. While a popular Lithium Ion (LiIon) battery can store 150 to 200 Watt-hours per kilogram of weight (Wh/kg), and a popular lead-acid battery such as is found in most vehicles can store 30 to 40 Wh/kg, current readily available commercial ultracapacitors are capable of storing about 3 Wh/kg of energy, with the newest and very best ultracapacitors being capable of storing about 60 Wh/kg. This means that an apparatus utilizing ultracapacitors for power storage would require 3 to 60 times the weight and size (and cost) as compared to utilizing LiIon batteries for power storage within a device, and up to 10 times the size and weight when comparing the use of common inexpensive lead-acid batteries to readily commercially available ultracapacitors. The size and weight added to a device using ultracapacitors, especially lower energy density commercially available ultracapacitors, could move many of the above mentioned devices from being classified as portable devices to being classified as non-portable devices. This could include some vehicles. Not only would this size, weight, and possibly cost difference cause most devices to be less convenient and less useful to users in general, but this would clearly change a major characteristic of some devices causing their usage to be minimized or avoided altogether by users.

### OBJECTS AND ADVANTAGES

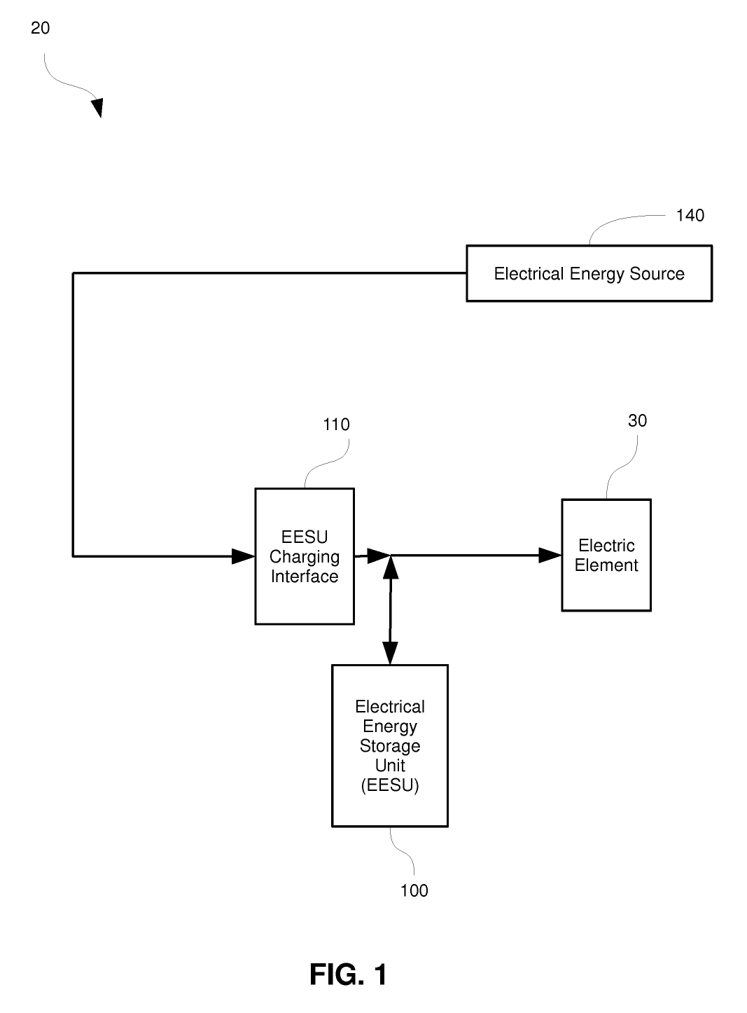

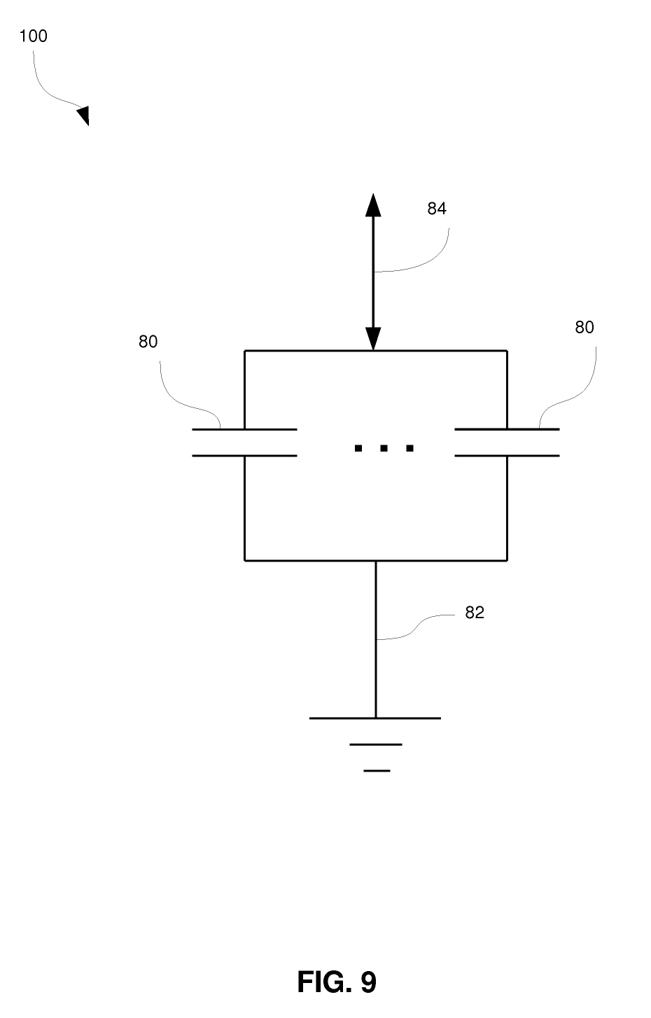

Accordingly, a solution to these issues is an apparatus, FIG. 1, that includes an electrical-energy-using element (electric element) such as a light, a display, an electrical or electronic component or circuit, a motor, or an electro-mechanical component, that is powered from a capacitive, ceramic-based electrical energy storage unit (EESU), FIG. 9, that is capable of storing large amounts of energy in a dense area, that is capable of accepting large charge currents without intermediate capacitors thereby allowing quick recharging with minimal costs, that does not show significant degradation over time, temperature, voltage, or with charge cycles, that does not show significant shelf-life issues, that has minimal impact on the environment, that includes a built-in charging circuit designed specifically for a high capacitive load and high voltages, and that includes on-board energy generation capable of recharging the power storage unit with energy generated on-board the device itself.

An example of one element of such an apparatus, the high density, capacitive, ceramic-based electrical energy storage unit, is the Electrical-Energy-Storage Unit (EESU) of Richard Dean Weir, U.S. Pat. No. 7,466,536 B1. The preferred embodiment of this referenced patent shows that integrated circuit techniques are utilized to sinter extremely high permittivity Barium Titanate crystals into a bulk ceramic substrate giving a very high-density capacitive energy storage capability. The referenced patent discusses a complete ceramic based EESU with 31,351 capacitive elements connected in parallel giving a total storage capacity of 52 kilowatt-hours (kWh) at a weight of 286 pounds. As the referenced patent states, this is enough electrical energy to power a vehicle for 300 miles. Other qualities are that the EESU of the above referenced patent can be charged in about five minutes, self-discharges slower than batteries and therefore has a long shelf-life, and it is non-explosive, non-toxic, and non-hazardous. According to TABLE 1 of the referenced patent, this EESU gives over twice the energy density of LiIon batteries and over five times the energy density of NiMH or any other high-density chemistry-based batteries.

Another element of an apparatus of this invention is the interface to charge the energy source, the EESU. An example of a charging circuit designed to handle the specific charging needs of an EESU is a circuit based around the LTC3751 high voltage capacitor charge controller integrated circuit from Linear Technology Inc. Specific circuitry within an EESU charging interface is determined by the voltages used in the apparatus and the manufacturer's preferred charge time requirements and cost goals for a particular apparatus. In particular, a high powered charger can be designed into an apparatus to accept charge quickly and to charge the device in minutes, or a lower powered charger can be designed into the apparatus to allow charging more slowly. This is unlike most battery charge controllers which utilize a somewhat generic, measured, chemistry changing charge algorithm specifically designed for the chemistry of a particular battery that can charge at a slow measured pace over an hour or more, but that does not have the capability to fully charge in minutes. Also, unlike battery chargers, a charger in an apparatus of this invention is designed to charge a highly capacitive load at high voltages and need not be sensitive to overcharging, overvoltage, or charging the EESU faster than a particular chemistry can handle it as with batteries.

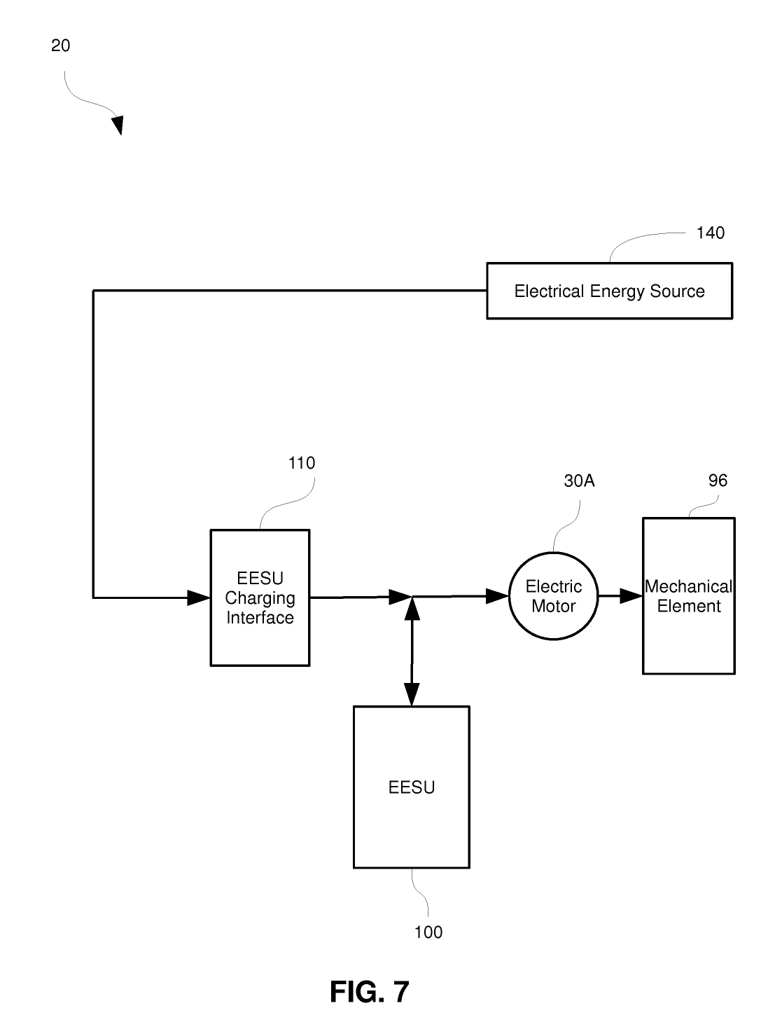

On-board energy generation to charge the EESU is yet another element of this invention. Electrical energy generation on devices of this invention can come from varied sources such as solar, wind, acoustic, static, electro-mechanical including motor feedback, man-powered such as would be found in exercise equipment, thermal, water-powered, as well as an electric generator powered by an internal combustion engine or a nuclear device, and others. Some prior art devices, such as vehicles and roadway signs that utilize an internal combustion engine as their sole energy source, have no capability for on-board energy generation. Utilizing this invention to create, for example, a vehicle or a roadway sign with on-board energy generation such as solar energy generation creates a device with unique reliability that is capable of charging itself while not in use, as well as being able to charge itself while in use, to extend its operating time before a full recharge is necessary. In current vehicles utilizing gasoline or diesel internal combustion engines as their sole energy source, the vehicles must stop at a filling station for all fuel, or fuel must be brought to them. For roadway signs, generally all fuel is delivered to the roadway sign, or all fuel is brought with the roadway sign to its destination. In either of these examples, there is no opportunity for gas or diesel fuel to be generated on the vehicle or on the roadway sign. This is the case for nearly all devices utilizing internal combustion engines as their sole energy sources. The exception is with hybrid vehicles that utilize batteries for their main electrical power storage that can collect energy that is generated on-board. Hybrid vehicles, though, also contain many of the shortfalls of battery based devices as described above. Creating a device of this invention, FIG. 7, such as a vehicle, that includes an EESU as its energy storage, an electric motor as its electric element to drive the wheels, and on-board energy generation to recharge its EESU through a charging interface, creates a useful device with unique reliability capable of recharging itself and extending its capabilities between full recharges.

The above referenced patent for an EESU covers one element of the current invention, an apparatus that is in and of itself a high density, capacitive, ceramic-based electrical energy storage unit. Versions of this EESU storage system, or other similar ceramic-based electrical energy storage units, can be made into various sizes, energy capacities and operating voltages to power any sized device. By combining an EESU of appropriate size, energy capacity, and voltage to deliver energy to an electric element such as a light, a display, an electrical or electronic system, a motor, or an electro-mechanical system, and by adding on-board energy generation and recharge circuitry specifically designed to charge the EESU, an apparatus of this invention is created. Many useful and reliable portable and non-portable devices of this invention can be created, including the exemplary battery-based devices as mentioned above, as well as electrical equivalents to the internal combustion engine based devices also mentioned above.

Advantages of devices of the current invention over prior art electro-chemical battery based devices include that an apparatus of the current invention will give the user a nearly unlimited lifetime of usefulness without the power storage unit requiring replacement. This is due to the energy generating capability, the recharge electronics, and the EESU power source within the device allowing a nearly unlimited number of recharge cycles with little degradation due to the number of recharge cycles, the number of deep charging cycles, extreme temperatures, or extreme voltages. On the other hand, batteries in battery-based devices degrade with usage and can be recharged only a limited number of times before their energy storing capabilities degrade to the point that the batteries need to be replaced. As an example, LiIon batteries as are used in electric vehicles can be cycled up to about 1200 times before needing replacement. Almost all other popular battery chemistries can be cycled fewer times than this before replacement is required. Deep cycling LiIon or other batteries or using them in extreme temperatures will further limit their charge holding capabilities and can require them to be changed out sooner. The longevity of these batteries can be of great interest to an owner of such a vehicle since replacement of such a large number of batteries can be very costly to the owner, possibly a significant percentage of the original cost of the vehicle. Similarly, owners of hybrid vehicles face battery replacement expenses after a number of years, although since these vehicles also have an internal combustion engine, deep cycling can be minimized and their usage can be extended. While battery life longevity in a vehicle will differ with battery type and with usage, nearly all experts agree that battery charge holding capabilities will degrade over time and that at some point the batteries will need to be replaced. Many times when batteries need to be replaced, the entire device is discarded due to the cost and effort to replace them. By utilizing the current invention, users are free to use their device without the concern of periodically changing out a portion of their device, and can realize significant cost savings by not having to do so.

This invention also has an advantage over an apparatus with an electro-chemical battery in that the power source of this invention requires only that charge be transferred from an energy source to the EESU and does not require the slow process of a chemistry change and the required measured timing for such a process as with electro-chemical batteries. The power source of an apparatus of this invention will accept charge quickly and is generally limited by the charge-handling capabilities of the cabling and the charging electronics. Charging an apparatus of this invention can therefore take place in minutes with proper charging equipment and with a proper energy source. This can be an obvious advantage to users in an electric vehicle who are on a long trip and who need to recharge quickly instead of waiting for recharge to occur over hours as with batteries. Even on-board energy generation such as regenerative braking can be quite effective on a vehicle of the current invention since the significant amounts of energy being generated quickly with the regenerative braking system can be stored into the EESU as it is generated with little loss and without requiring intermediate storage devices which add size, weight, and cost.

Size and weight are another advantage for an apparatus of the current invention. This is because the energy density of the EESU power source in the current invention is greater than that of popular electro-chemical batteries. Thus a device of this invention with an EESU power source can give the user more power and more useful operation time than a prior art device with a battery or an ultracapacitor of comparable size and weight.

Another advantage of the invention is that a capacitive-based energy storage system based on the Electrical-Energy-Storage Unit (EESU) of Richard Dean Weir, U.S. Pat. No. 7,466,536 B1, or a system with similar qualities, will not show limiting shelf life issues to affect its usefulness after a period of time as with a battery. This will minimize or nearly eliminate the costs and inconvenience due to replacement issues, not to mention minimizing the waste, and possibly the toxic waste, associated with the disposal of millions of chemical-based batteries yearly. There will also be no need to utilize energy to recycle millions of recyclable batteries.

Reliability is a key advantage for a device of this invention when compared to a device based on a battery. Far more reliable and therefore more cost effective devices can be built around an EESU power source due to the reliability of the EESU itself. This opens up a large number of potential new uses. Examples are remote road side warning signs and power generators with solar collectors that would utilize an EESU to store power instead of a battery. Utilizing batteries in these situations may be unsuitable due to extreme temperatures, limited shelf life, and so called battery chemistry memory issues that over time can significantly diminish the amount of electric charge available for use when needed. For batteries, these issues all bring maintenance and cost issues, but more importantly they bring reliability issues that could cause the device to fail just when it is needed most. This can have the effect of rendering useless all user efforts and costs to ensure reliable usage or backup of valuable systems. Devices of this invention, however, would incur none of these negative issues and will be capable of performing without incident over extended periods of time and in harsh environments. Utilizing solar, wind, or other on-board energy generation methods will allow devices of this invention to operate reliably for extended periods without significant performance degradation over time as with battery based devices.

Yet another advantage of this invention is that it will power relatively clean electric motors to replace internal combustion engines in many devices. These clean electric motors will not require the mess of handling fuels and large quantities of oils as with internal combustion engines. Nor will the constant maintenance of internal combustion engines be required. Even energy availability will be less of an issue with this invention since energy recharge is accomplished by recharging with on-board energy generation or by charging the EESU power source anywhere the currently available electric grid is available. No longer will the major overheads of time, effort, and cost be required to deliver fuel to thousands of filling stations to make it available to users, and no longer will users be required to travel miles to a filling station to get fuel, and then to store potentially dangerous and messy fuels at their homes or work locations for portable devices. Utilizing this invention in devices instead of gas or diesel engines will also eliminate the exhaust of millions of combustible engines thereby reducing pollution and heat that could be factors in global warming.

As can be readily seen throughout the commercial, industrial, and military world, while current supercapacitors or ultracapacitors have their places, they are generally not utilized in the above mentioned devices as sole energy sources. This is because of their limited energy density and the large overall apparatus size that would be realized when utilizing these energy storage devices for power storage, possibly moving a device from being classified as a portable device to being classified as a non-portable device, thereby completely changing the nature and usefulness of the device for users.

While the best ultracapacitors demonstrate energy density of 3 to 60 Wh/kg, with typical commercially available unit power capacities being closer to 3 Wh/kg, the EESU of the above referenced patent is capable of energy density of about 400 Wh/kg giving it from 6 to over 100 times the energy density. Therefore the size and weight of an ultracapacitor storage unit for the devices mentioned above would have to be over 6 to 100 times the size and weight of an EESU storage unit that is capable of storing an equivalent amount of energy. Contrast this to using an EESU in one of the above mentioned devices. The energy density of an EESU is over twice that of current LiIon batteries with 150 to 200 Wh/kg of energy density. This will allow devices of this invention to become even smaller and more convenient for users than devices currently based on LiIon batteries.

As an example, for a 2000 pound vehicle to travel 300 miles, approximately 52 kilowatt-hours (kWh) of energy will be required (as shown in the above referenced patent). A vehicle can travel this distance utilizing a 286 pound EESU power source that is capable of storing 52 kWh of energy. Equivalently, to travel this distance it would take a vehicle capable of handling the size and weight of ultracapacitors weighing from 1,800 pounds to 36,000 pounds just for the ultracapacitor power storage, with generally available ultracapacitors weighing closer to 36,000 pounds. This would change vehicles as we know them today. This could very well change their usefulness to users. Their usability for many applications might come into question. The same argument can be used for many of the above mentioned devices. Instead of giving devices features that include the greater conveniences to the user of being smaller, lighter weight, easer to handle, and more portable, the character of the devices could change dramatically to being larger, heaver, more awkward to handle, and less portable, if their character and usefulness could then be classified as portable at all. The nature and usability of some the devices could be changed completely.

Also, while an ultracapacitor can experience a loss of power storing and usage capabilities during extreme conditions such as charging and discharging at high temperatures, excessive charging voltages, or even when a power unit sits unused for long periods of time such as might occur in military and emergency uses, an EESU of the above referenced patent does not degrade with temperatures or overvoltages with even the highest generally available voltages (less than 5×10̂6 Volts).

As can be seen above, devices of the current invention have operational features and capabilities that are markedly different from prior art devices powered by batteries, by internal combustion engines, or by capacitors and ultracapacitors.

Table 1 below shows that while most batteries of various chemistry make-ups show mostly similar traits, an apparatus of this invention shows capabilities of being able to operate in different environments, with different limitations, and with different features, than a battery based apparatus that performs a similar function.

Similarly, Table 2 show that a device of this invention offers significant operational differences and features from a device powered by an internal combustion engine that performs a similar function.

And in Table 3, a device of this invention can clearly be seen as useful in portable devices since the energy density of the EESU power source within the device is far smaller than for equivalent ultracapacitor power sources for devices, and is even twice that of popular LiIon batteries, therefore giving the potential for an even smaller power source and an even smaller overall apparatus size than is generally available today, thereby giving the user even more portability and convenience. On the other hand, a similar device utilizing prior art ultracapacitors as a power source would be of such a size and weight that its use as a portable device would be limited and could possibly be seen as changing the device from a portable device to a non-portable device, thereby changing the nature and usefulness of the device for the user completely. Very possibly only trains and some extreme military or national defense devices could be considered viable portable devices with such a large and heavy power source.

TABLE 1
Operational And Functional Feature Differences:
Prior Art Battery Powered Apparatus vs. Current Invention Apparatus

| A Prior Art Apparatus With Electro- | An Apparatus Of This Invention |
|---|---|
| Chemical Battery Power Source | With An EESU Power Source |
| Expect Unreliable Apparatus Performance | Expect The Same Reliable Apparatus |
| After A Period Of Time | Performance Indefinitely |
| Due to Battery Chemistry Degradation | No Chemistry To Degrade In EESU |
| Due to Battery “Memory Effect” | No “Memory Effect” In EESU |
| Due to Battery “Deep Cycling” | No Issues Due To “Deep Cycling” In |
| | EESU |
| Expect To Change Out Apparatus Battery After | No Need To Change Out Apparatus EESU |
| A Period Of Time Due To “Normal Wear” | Because Of “Normal Wear” |
| Time And Effort Inconvenience For User | No Inconvenience To User |
| Cost For User | No Cost To User |
| Device Itself Becomes Unusable If | Apparatus Generally Only Becomes |
| Replacement Battery Not Found Or Is | Unusable With Mechanical Element |
| Not Cost Effective | Wear Or Breakage |
| If Apparatus Uses “Throw Away” Batteries, | Apparatus Uses Rechargeable EESU, It Is Not |
| Expect To Pollute The Environment After | A “Throw Away”, It Is Rechargeable |
| Battery Is Discharged And Discarded | Indefinitely. EESU Is Ceramic Based, |
| | No Toxic Pollution When Discarded |
| If Apparatus Utilizes Recyclable Battery, | Apparatus Will Generally Not Degrade To The |
| Expect To Require Time, Effort, And Cost To | Point Of Requiring EESU Replacement. |
| Recycle Battery After A Period Of Time | EESU Could Possibly Be Used Or Sold As |
| | Useful Power Storage Device |
| | Even After The Rest Of The Apparatus |
| | Is Discarded Or Replaced |
| After Apparatus Battery Is Discharged, | After Apparatus EESU Is Discharged, |
| Apparatus Is Unusable Until Battery Is | Apparatus Is Unusable Until EESU Is |
| Charged Or Changed Out | Charged Or Changed Out |
| Battery Requires Electro-Chemical | EESU Needs Only To Transfer Charge, |
| Transfer, Charges Slowly At A Measured | Charging Can Take Place In Minutes |
| Pace Over Hours To Charge Fully | Fast Charge To Full Charge In EESU |
| Fast Charge To Full Charge Is Generally | Is Standard Practice |
| Not Possible With Batteries | Replacement EESU Is Not Required If |
| Replacement Battery Is Generally Used | User Can Wait Minutes For Recharge |
| While Primary Battery Is Charging | (Or Possibly Less Than A Minute In |
| Second, Third, Or Even Fourth | Small EESUs) |
| Replacement Battery Sometimes | Second EESU Can Be Used When No Wait |
| Required During Primary Battery Charge | Time Is Preferred By User |
| Period | |
| Extreme Temperatures Limit Usefulness And | Extreme Temperatures Do Not Limit |
| Reliability Of Apparatus With Battery Due To | Usefulness Of Apparatus Due To EESU, |
| Battery Chemistry Issues | Although Other Electronics And Mechanicals |
| | Possibly Affect Reliability |

TABLE 2
Operational And Functional Feature Differences:
Prior Art Internal Combustion Engine Powered Apparatus vs. Current Invention Apparatus

| Prior Art Apparatus | Apparatus Of This Invention |
|---|---|
| With Fuel Engine Power Source | With EESU Power Source |
| Apparatus Takes Only Minutes To Refuel | Apparatus Takes Only Minutes To Recharge |
| Apparatus Is Usually Noisy Due To | Apparatus Is Usually Quiet Due To |
| Engine Noise | Electric Motor Being Relatively Quiet |
| Muffler Always Required | No Muffler Required |
| Apparatus Requires User Deal With Fuels | Apparatus Is Clean And Requires User To |
| That Are Explosive, Toxic, And “Messy” | Power Device Somewhat Like Many Current |
| | Home Appliances And Tools |
| To Fuel Apparatus, Travel To A “Gas Station” | Charging Apparatus Can Be Done Anywhere |
| Required | From The Current Electric Grid, |
| | Even From Home Or Work |
| Fuels To Refuel Apparatus Must Be | Energy To “Recharge” Apparatus Is Available |
| Transported Via Trucks To “Gas Stations” | Everywhere The Electric Grid Is Available |
| Requires Transport Time, | Electricity Delivery Costs And |
| Transport Cost, And | Maintenance Is Shared With Current |
| Pollution From Delivery Trucks | Electric Grid Users |
| Extra Fuel Can Travel With Apparatus To | Extra Replaceable EESU Power Modules Can |
| Refuel Anywhere | Travel With Apparatus To Replace |
| | Discharged Modules Anywhere |
| Apparatus Emits Exhaust Emissions | Apparatus Emits No Exhaust Emissions, |
| | Not Even Vent Gasses |
| Engines In Apparatus Require Periodic | Apparatus Motor Requires Little Maintenance, |
| ”Tune Up” And Maintenance | Similar To High Use Air Conditioning |
| | Condenser Or Fan Motors |
| Apparatus Complicated By | Apparatus Similar To |
| Complex Mechanical Engine | Simple Electric “Appliance” |
| Apparatus Utilizes Fuel Energy Inefficiently | Apparatus Energy Utilization Is More Efficient |
| Internal Combustion Engine Overall | Than For Internal Combustion Engine |
| Efficiency At Converting Energy To | Apparatus |
| Useful Work Is Low | Even After Electricity Generation, A |
| Fuel Engines Utilize Energy Even At Idle | Vehicle With An Electric Motor Is Nearly |
| Times When No Useful Work Is Done | Twice As Efficient As A Vehicle With An |
| | Internal Combustion Engine |
| | Energy Usage Can Be Stopped During |
| | Idle Periods To Conserve Energy |

TABLE 3
Operational And Functional Feature Differences:
Prior Art UltraCapacitor Powered Apparatus vs. Current Invention Apparatus

| Prior Art Apparatus | Apparatus Of This Invention |
|---|---|
| With UltraCapacitor Power Source | With EESU Power Source |
| Apparatus capable of 10 year life with little | Apparatus capable of greater than 10 year life |
| power source degradation unless used in | regardless of extreme temperatures or voltages. |
| extreme temperatures, voltages or storage | |
| situations. | |
| Size and Weight, due to limited energy density, | Size and Weight, due to high energy density, |
| restricts apparatus from being portable in all but | allows smallest and lightest apparatus |
| extreme applications. | compared to any capacitor or popular electro- |
| | chemical battery based apparatus, inviting use |
| | in all portable devices and applications. |

Through the comparisons shown in Tables 1, 2 and 3, it can be seen that an apparatus of this invention has distinctively different operational capabilities and features than either a prior art battery based apparatus, a prior art apparatus with an internal combustion engine, or a prior art capacitor or ultracapacitor based apparatus. Even hybrid vehicles with gasoline engines, batteries, and capacitors are not only different, but include many of the differences of each prior art apparatus, a battery based apparatus, an engine based apparatus, and a capacitor based apparatus, each with their own clear differences.

There are also differences in the built-in charging circuits of an apparatus of the current invention verses a prior art apparatus utilizing a battery as an energy storage source. While an EESU charging circuit can be designed to charge an EESU to a full charge within minutes or over a longer period of time, a prior art battery charger can only charge to a full charge at a slower speed, generally over an hour. And while an EESU charging circuit can charge utilizing general voltage and charge current targets, a prior art battery charger must utilize charging algorithms to provide varying voltages and currents at different stages of the charging process to suit the particular chemistry make-up of the battery, and they must closely monitor conditions that could lead to overvoltage, overcurrent, and overheating. Even prior art capacitor and ultracapacitor charging circuits must use caution to avoid allowing overvoltage lest the charge carrying capabilities and the charge releasing capabilities of the capacitor be degraded. The EESU, as described in the above referenced patent, does not exhibit these limitations for even the highest of generally available voltages.

As can readily be seen, an apparatus of the current invention utilizing as its power source an EESU such as that in the above referenced patent, or a similar ceramic based energy storage device with similar qualities, has a significant advantage over an apparatus designed for a similar use that utilizes a prior art electro-chemical battery as a power source. Therefore it can be easily seen by one skilled in the art that an apparatus of this invention is clearly not just another battery based device with a new type of battery that includes many of the prior art electro-chemical battery's features and limitations.

Likewise, since an apparatus of the current invention utilizing an EESU as its power source has the advantage of allowing nearly any of the above mentioned devices to have smaller sizes and weights than current prior art devices, thus allowing many of them to be portable, an apparatus of this invention clearly has different features and operational capabilities than prior art devices utilizing capacitors or ultracapacitors as their power source.

Other objects of this invention and advantages of this invention will become apparent from a consideration of the ensuing description and drawings.

Thank you, Lord, for this great inspiration. Thank you Spirit of God for your guidance.

### SUMMARY

In accordance with the present invention, an apparatus includes an electrical-energy-using element (electric element) such as a light, an electrical or electronic component, a motor, or an electromechanical device, and a capacitive, ceramic-based electrical energy storage unit (EESU) that is capable of operating as a power source, or possibly as a primary power source, for the electric element within the apparatus, the EESU within the apparatus being capable of being recharged via a built-in charging interface with energy from an on-board energy generation source.

### DRAWINGS

### Figures

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, or characteristic included in at least one implementation of the invention. Thus, phrases such as “in an embodiment” or “in an alternate embodiment” appearing herein describe various embodiments and implementations of the invention, and do not necessarily all refer to the same embodiment, however, they are also not necessarily mutually exclusive.

FIG. 1 shows an apparatus with an electric element, an EESU, an EESU charging interface, and an electrical energy source, according to an embodiment of the invention.

FIG. 2 shows a prior art apparatus with a non-rechargeable battery.

FIG. 3 shows a prior art apparatus with a rechargeable battery.

FIG. 4 shows a prior art stand-alone battery charger and rechargeable battery.

FIG. 5 shows a prior art apparatus with an electric element, a rechargeable battery, a battery charge controller circuit, and an electrical energy source.

FIG. 6 shows a prior art apparatus with a mechanical element, a combustible engine, and a fuel reservoir.

FIG. 7 shows an apparatus with a mechanical element, an electric motor as the electric element, an EESU, an EESU charging interface, and an electrical energy source, according to an embodiment of the invention.

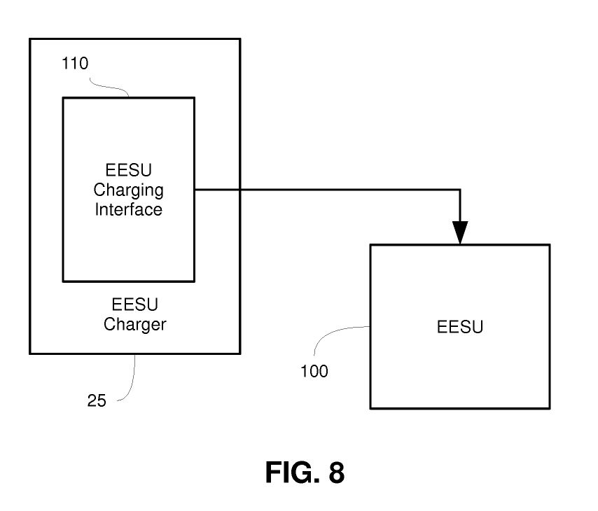

FIG. 8 shows a stand-alone EESU charger and an EESU.

FIG. 9 shows an EESU with multiple capacitive elements, an Input/Output interface, and a common interface.

### REFERENCE NUMERALS

20 An Apparatus
22 Stand-Alone Battery Charger
25 Stand-Alone EESU Charger
30 Electric Element
30A Electric Motor as Electric Element
50 Non-Rechargeable Battery
60 Rechargeable Battery
62 Battery Charge Controller
80 EESU Capacitive Element
82 EESU Common
84 EESU Input/Output
90 Combustible Engine
92 Fuel Reservoir for Combustible Engine
96 Mechanical Element
100 Multi-Capacitor-Energy-Storage System (EESU)
110 EESU Charging Interface
140 Electrical Energy Source

### DETAILED DESCRIPTION AND OPERATION

### FIG. 1—Preferred Embodiment

An embodiment of an apparatus of the present invention is illustrated in FIG. 1. An apparatus 20 includes an electrical energy storage unit (EESU) 100 to store and supply electrical energy within the apparatus, an EESU charging interface 110 to allow charging of the EESU 100, an electrical energy source 140 to provide electrical energy to charge the EESU 100, and an electric element 30 such as a light, an electronic or electrical system, a motor-driven mechanical system, or some other electro-mechanical system to provide a useful output to the user.

The EESU 100 is made up of multiple capacitive elements 80 connected together, FIG. 9. As with most capacitors, there is a common reference 82 interface, and an input/output 84 interface.

The on-board EESU charging interface 110 within the apparatus of this embodiment of the invention can be similar to that of the EESU charging interface 110 in the stand-alone EESU charger 25 of FIG. 8. An example of an EESU charging interface 110 is a complex integrated circuit capable of charge transfer to a capacitive device, with voltage regulation, and with discrete circuitry around it. Another example is a simple electrical, mechanical, or combination electrical and mechanical interface.

An example of an electrical energy source 140 is a solar voltaic cell, or a group thereof, such as those used commonly in calculators, although any electrical energy generating source is appropriate for use in this invention.

Prior art apparatus that offer similar utility features to that of the current invention are shown in FIGS. 2, 3, and 5, with FIG. 4 being an illustration of a prior art stand-alone battery charger 22 and a prior art rechargeable battery 60. Similar to the embodiment of FIG. 1, the prior art apparatus of FIG. 5 features an electric element 30 as a useful output for the user, a rechargeable battery 60 to provide power to the electric element 30, a built-in battery charge controller 62 to charge the battery, and an electrical energy source 140 to provide electrical energy to charge the battery.

### Operation—FIGS. 1, 2, 3, 4, 5

Operational features of the FIG. 1 embodiment of the current invention are similar to those of prior art apparatus as shown in FIGS. 2, 3, 4, and 5. FIG. 2 shows a prior art apparatus that uses a standard, non-rechargeable battery 50 as the primary energy source to power an electric element 30 such as a light, an electronic or electrical system, a motor-driven mechanical system, or some other electro-mechanical system. FIG. 3 shows an apparatus in a configuration to power an electric element 30 as in FIG. 2, but with the enhancement of using a rechargeable battery 60.

FIG. 5 shows a prior art system similar to the embodiment of FIG. 1 but with a rechargeable battery 60 as the primary electrical energy source powering an electric element 30, a battery charge controller 62 as an enhancement to the apparatus of FIG. 3 that controls the charge process for the rechargeable battery 60, and an electrical energy source 140 also as an enhancement to the apparatus of FIG. 3 providing electrical energy to charge the battery.

The operation for this embodiment of this invention, FIG. 1, is similar to that of the prior art apparatus 20 of FIG. 5. In normal operation electrical energy flows from the primary energy source, the EESU 100, to the electric element 30, and the electric element 30 operates in the manner for which it was designed. As energy is utilized to power the electric element 30, energy within the EESU 100 is depleted. The EESU 100 is recharged via the EESU charging interface 110 with energy from the electrical energy generation source 140.

An exemplary apparatus 20 of the invention is a flashing school zone crosswalk light as the electrical element 30, a solar collector as the electrical energy source 140 storing its energy into an EESU 100 as its energy storage unit, and a built-in EESU charging circuit 110 to charge the EESU 100.

An exemplary EESU would be a electrical energy storage unit based on the Electrical-Energy-Storage Unit (EESU) of Richard Dean Weir, U.S. Pat. No. 7,466,536 B1, or a system with similar qualities, designed appropriately for a flashing school zone crosswalk light.

An exemplary EESU charging circuit 110 is based on an LT3751 high voltage capacitor charger controller integrated circuit from Linear Technology. Along with appropriate periphery circuitry, examples of which are shown for specific configurations in the data sheet for the LT3751, the LT3751 capacitor charger controller may optionally require voltage regulation circuitry at its input to be powered from a solar collector, depending on the solar collector chosen for use.

An exemplary solar collector can be made from XOB17-01×8 solar components from IXYS. A single unit gives a 4.90 Volt typical open circuit voltage output with a 4.2 miliamperes (mA) short circuit current. Utilizing multiple of these solar components in parallel or in series within an apparatus can give larger charge current capability, larger charge voltage capability, or both.

Under normal circumstances, energy is being stored into the EESU 100 via the EESU charge controller 110 whenever there is light enough to generate electrical energy from the solar collector 140. During periods when the school zone speeds are in effect for the crosswalk, the flashing school zone crosswalk light 30 operates from electrical energy previously stored into the EESU 100.

### FIGS. 6, 7

### Additional Embodiment

FIG. 7 shows an additional embodiment of the current invention. An apparatus 20 includes a mechanical element 96 to provide a useful output for the user, an electric motor 30A as the electric element to provide motion for the mechanical element, an EESU 100 for energy storage and supply within the apparatus, an EESU charging interface 110 to charge the EESU 100, and an on-board electrical energy generation source 140 to provide energy to charge the EESU 100.

### Operation—FIGS. 6, 7

The operation for the apparatus 20 of this embodiment of the invention is such that the electric motor 30A operates as the electric element of the invention to drive the mechanical element 96. The EESU supplies electrical energy to power the electric motor 30A. As energy is utilized to power the electric motor 30A, energy within the EESU 100 is depleted. The EESU 100 is charged by passing energy from the electrical energy generating source 140 through the EESU charging interface 110 to the EESU 100.

An exemplary apparatus 20 of this embodiment of the invention is a vehicle with an electric motor/controller combination as the electric element 30, directly driving a wheel as the mechanical element 96, and with a solar collector as the electrical energy source 140 to charge the EESU 100 when in sunlight, FIG. 7.

The common prior art vehicle, FIG. 6, utilizes a gasoline engine 90 to drive a mechanical element 96, the wheel. The energy for the gasoline engine 90 is stored in the vehicles' gasoline storage tank 92. To recharge the gasoline powered vehicle, a user would refill the gasoline storage tank 92. Built-in energy sources, such as electrical energy source 140, are not available on most prior art gasoline powered vehicles.

An exemplary electric motor/controller combination is GE part number M9164 for the motor and Yaskawa part number P7U20370 for the motor controller.

An exemplary EESU is an electrical energy storage unit based on the Electrical-Energy-Storage Unit (EESU) of Richard Dean Weir, U.S. Pat. No. 7,466,536 B1, or a system with similar qualities, designed appropriately for a vehicle.

An exemplary EESU charging circuit 110 includes a circuit based on the LT3751 high voltage capacitor charger controller integrated circuit from Linear Technology.

An exemplary solar collector can be made from XOB17-01x8 solar components from IXYS. Utilizing multiple of these solar components within the vehicle can give multiple watts of power to recharge the EESU 100 during much of the day.

A vehicle of this embodiment, FIG. 7, utilizes the GE M9164 motor and Yaskawa P7U20370 motor controller combination 30A to drive the wheel 96. The EESU supplies electrical energy to power the motor/controller 30A. As energy is utilized to power the motor/controller 30A, energy within the EESU 100 is depleted. The LT3751 high voltage capacitor charger controller 110 recharges the EESU 100 with energy from the IXYS XOB17-01x8 solar components that make up the electrical energy source 140. The solar collector can recharge the EESU whenever sunlight is available, either while being used or while being stored. While this exemplary apparatus is not optimized, it shows the basic concepts involved in this invention.

### CONCLUSION, RAMIFICATIONS, AND SCOPE

Thus the reader can see that many useful, convenient and reliable devices can be created for users utilizing the elements of this invention, devices with unique features and operational capabilities that are distinct from prior art devices based on electro-chemical batteries, internal combustion engines, or ultracapacitors.

Improvements over prior art devices include greatly enhanced reliability due to nearly unlimited recharge capability, the ability to recharge from nearly anywhere on the current electric grid, the ruggedness over temperature and voltage variations, and the enhanced shelf life of the EESU within the device. A device of this invention has minimal impact on the environmental as compared to prior art devices. Recharging devices of this invention affords long lasting convenience to the user while requiring little need for the user to change out or discard an EESU as with prior art batteries, thus eliminating much waste and pollution being added to the environment. Also, when comparing an apparatus of this invention with an apparatus based on an internal combustion engine, a user can expect lower pollution, less mess, and lower overall energy usage. The capability of a device of this invention to be compact due to the EESU having a higher energy density than batteries or ultracapacitors can make many devices portable and convenient, and can therefore make them more useful to users than is possible with prior art devices, especially devices based on prior art capacitors.

Thus the combination of better overall reliability as well as smaller size, better portability, better durability, reduced waste, reduced pollution, and better user convenience are the features that make a device of this invention unique as compared to prior art devices.

While the above description contains many specificities, these should not be construed as limitations on the scope of the invention, but rather as exemplifications of preferred embodiments thereof. Many other variations are possible. For example, the EESU need not be limited to the EESU of Richard Dean Weir, U.S. Pat. No. 7,466,536 B1. Other capacitive, ceramic-based electrical energy storage units utilizing ceramic sintered with other substances of high permittivity may also be utilized. Of course various storage capacities, various unit sizes, and various operating voltages may also be utilized.

The on-board EESU charging interface can consist of any interface capable of charging the EESU, not just electronic circuitry based on the LT3751 high voltage capacitor charger controller integrated circuit as exemplified above.

The on-board electrical energy source is not limited to a solar collector based on the XOB17-01x8 solar components from IXYS. Any solar components, or group of solar components, will fulfill the requirements of this element of this invention. Also, energy generation on devices of this invention is not limited to solar devices, but can come from any electrical energy generation source including solar, wind, acoustic, static, electro-mechanical including electric motor feedback, man-powered, thermal, water-powered, as well as an electric generator powered by a combustible engine, and others.

An electric element can consist of not just a light, an electronic or electrical component or circuit, a motor-driven mechanical system, or some other electro-mechanical system, but of any electric element capable of being driven by an electrical energy source in an apparatus.

Thus the scope of the invention should be determined by the appended claims and their legal equivalents, rather than by the examples given.

I claim:

1. An apparatus, comprising:
an electrical-energy-using element (electric element),
a capacitive, ceramic-based electrical energy storage unit (EESU),
an interface capable of charging said EESU, and
an electrical energy source,
wherein said EESU is capable of operating as a power source for said electric element and said interface capable of charging said EESU is capable of charging said EESU with energy from said electrical energy source.

2. The electrical energy storage unit (EESU) of claim 1 wherein said EESU is rechargeable.

3. The electric element of claim 1 wherein said element includes a light.

4. The electric element of claim 1 wherein said element includes an electronic circuit.

5. The electric element of claim 1 wherein said element includes an electrical component.

6. The electric element of claim 1 wherein said element includes an electric motor.

7. The electric element of claim 6, wherein said electric motor drives a mechanical element.

8. The interface for charging said EESU of claim 1 wherein said interface includes an on/off switch mechanism.

9. The interface for charging said EESU of claim 1 wherein said interface includes voltage conversion circuitry.

10. The interface for charging said EESU of claim 1 wherein said interface includes charge transfer circuitry.

11. The interface for charging said EESU of claim 1 wherein said interface includes charge control circuitry.

12. The electrical energy source of claim 1 wherein said electrical energy source includes solar electrical energy generation.

13. The electrical energy source of claim 1 wherein said electrical energy source includes wind electrical energy generation.

14. The electrical energy source of claim 1 wherein said electrical energy source includes electro-mechanical electrical energy generation including electric motor feedback.

15. The electrical energy source of claim 1 wherein said electrical energy source includes acoustic electrical energy generation.

16. The electrical energy source of claim 1 wherein said electrical energy source includes static electrical energy generation.

17. The electrical energy source of claim 1 wherein said electrical energy source includes man-powered electrical energy generation.

18. The electrical energy source of claim 1 wherein said electrical energy source includes electrical energy generation driven by an internal combustion engine.

19. An apparatus, comprising:
an electrical-energy-using element (electric element),
a capacitive, ceramic-based electrical energy storage unit (EESU),
an interface capable of charging said EESU, and
a means for generating electrical energy,
wherein said EESU is capable of operating as the primary power source for said electric element and said interface capable of charging said EESU is capable of charging said EESU with energy from said means for generating electrical energy.

20. In an apparatus, a method of delivering electrical energy comprising:
supplying electrical energy to an electrical-energy-using element (electric element) from a capacitive, ceramic-based electrical energy storage system (EESU), and charging said EESU through an interface capable of charging said EESU with energy from an electrical energy source.
